(19) United States
(12) Patent Application Publication
(10) Pub. No.: US 2023/0187402 A1
(43) Pub. Date: Jun. 15, 2023

(54) ELECTRONIC PACKAGE AND MANUFACTURING METHOD THEREOF

(71) Applicant: PHOENIX PIONEER TECHNOLOGY CO., LTD., Hsinchu County (TW)

(72) Inventors: Wen-Chang CHEN, Hsinchu County (TW); Che-Wei HSU, Hsinchu County (TW)

(21) Appl. No.: 18/072,694

(22) Filed: Nov. 30, 2022

(30) Foreign Application Priority Data
Dec. 9, 2021 (TW) 110146061

(51) Int. Cl. H01L 23/00; H01L 23/31; H01L 21/56

(52) U.S. Cl. CPC H01L 24/24; H01L 23/3107; H01L 21/56; H01L 2224/24011

(57) ABSTRACT

An electronic package is provided, in which a surface treatment layer is formed on parts of a surface of a functional pad, such that an electronic element is in contact with and bonded to the functional pad and the surface treatment layer via a bonding layer. Therefore, when the electronic package undergoes thermal shock, the surface treatment layer having buffering capability can improve packaging reliability of the electronic package.

### BACKGROUND

### 1. Technical Field

The present disclosure relates to a semiconductor packaging structure and manufacturing process thereof, and more particularly, to an electronic package and a manufacturing method thereof that can improve packaging reliability.

### 2. Description of Related Art

With the vigorous development of the electronic industry, electronic products are gradually moving towards the trend of multi-function and high performance. In order to meet the packaging requirements of miniaturization of electronic packaging structure, the technology of wafer level packaging (WLP) or chip scale package (CSP) has been developed.

FIG. 1A is a schematic cross-sectional view of a conventional CSP semiconductor package 1. As shown in FIG. 1A, in the manufacturing process of the semiconductor package 1, a copper pad 10 and a plurality of electrical contact pads 11 are formed on a carrier (not shown), and an adhesive 13 is coated on the copper pad 10 to adhere a semiconductor chip 12 on the copper pad 10, and conductive pillars 14 are formed on the electrical contact pads 11; then, the semiconductor chip 12, the copper pad 10, the electrical contact pads 11 and the conductive pillars 14 are covered by a packaging layer 15; afterward, a circuit structure 16 is formed on the packaging layer 15, so that the circuit structure 16 is electrically connected to the conductive pillars 14 and the semiconductor chip 12; and finally, the carrier is removed.

However, in the conventional semiconductor package 1, the adhesive 13 is located between the copper pad 10 and the semiconductor chip 12, and because the copper pad 10 and the semiconductor chip 12 are rigid members of different materials, and the adhesive 13 is a non-rigid member, so under the thermal expansion and contraction of the manufacturing process, the bonding between an upper side and a lower side of the adhesive 13 is prone to unidirectional abnormality, resulting in poor adhesion between the copper pad 10 and the adhesive 13. Therefore, the semiconductor chip 12 is prone to misalignment or even fall off at the connection interface of the adhesive 13 where the bonding is weak, resulting in reliability problems of the semiconductor package 1.

Furthermore, as shown in FIG. 1B, the industry then forms a strengthening layer 18 such as other metal materials (e.g., electroplating nickel-gold, electroplating silver, or chemically depositing non-copper metal materials, etc.) on the entire top surface of the copper pad 10 to strengthen the bonding with the adhesive 13, but doing so also weaken the adhesiveness between the adhesive 13 and the semiconductor chip 12, which result in reliability problems between the semiconductor chip 12 and the adhesive 13 (for example, in the thermal shock process, a separation occurs between the semiconductor chip 12 and the adhesive 13). Therefore, the formation of the strengthening layer 18 will increase the production cost.

Therefore, there is a need for a solution that addresses the aforementioned shortcomings in the prior art.

### SUMMARY

In view of the aforementioned shortcomings of the prior art, the present disclosure provides an electronic package, which comprises: a patterned metal layer comprising at least one functional pad and a first circuit layer; a surface treatment layer disposed on parts of a surface of the functional pad; a bonding layer disposed on the functional pad and the surface treatment layer; an electronic element disposed on the bonding layer and being bonded onto the functional pad and the surface treatment layer via the bonding layer, wherein the electronic element is provided with a plurality of electrical connection pads; a packaging layer covering the electronic element and the patterned metal layer, wherein a part of a bottom surface of the first circuit layer is exposed from the packaging layer to serve as an external pad; and a build-up circuit structure bonded with the packaging layer and electrically connected to the electrical connection pads of the electronic element and the first circuit layer.

In the aforementioned electronic package, the surface treatment layer is uniformly or non-uniformly distributed on the parts of the surface of the functional pad.

In the aforementioned electronic package, the functional pad and the surface treatment layer are made of different metal materials.

In the aforementioned electronic package, the bonding layer is a conductive adhesive or an insulating adhesive.

In the aforementioned electronic package, the build-up circuit structure is electrically connected to the electrical connection pads of the electronic element via fan-out conductors. For example, the fan-out conductors are formed as cylinders conformed to a geometry of the electrical connection pads of the electronic element.

The present disclosure further provides a method of manufacturing an electronic package, the method comprises: providing a carrier having at least one metal surface; electroplating a patterned metal layer on the carrier by patterned exposure and development, wherein the patterned metal layer comprises at least one functional pad and a first circuit layer; forming a surface treatment layer on parts of a surface of the functional pad; forming a bonding layer on the functional pad and the surface treatment layer; disposing an electronic element on the bonding layer, wherein the electronic element has a plurality of electrical connection pads; forming a plurality of conductive pillars on a part of the first circuit layer by patterned exposure and development; covering the electronic element and the plurality of conductive pillars by a packaging layer; electroplating a second circuit layer on the packaging layer by patterned exposure and development, wherein the second circuit layer is electrically connected to the electronic element and the plurality of conductive pillars; and removing the carrier to expose a part of a bottom surface of the first circuit layer for serving as an external pad.

In the aforementioned method, the surface treatment layer is uniformly or non-uniformly distributed on the parts of the surface of the functional pad.

In the aforementioned method, the functional pad and the surface treatment layer are made of different metal materials.

The aforementioned method further comprises forming column-shaped fan-out conductors simultaneously on the electrical connection pads of the electronic element when forming the plurality of conductive pillars. For example, the fan-out conductors are cylinders conformed to a geometry of the electrical connection pads of the electronic element.

The aforementioned method further comprises exposing the electrical connection pads of the electronic element with openings formed by a laser after forming the packaging layer, and forming conductive blind vias simultaneously when forming the second circuit layer subsequently, wherein the conductive blind vias are electrically connected to the second circuit layer and the electrical connection pads of the electronic element.

As can be understood from the above, in the electronic package and a manufacturing method thereof according to the present disclosure, the surface treatment layer is formed on parts of the surface of the functional pad, so that the bonding layer may be in contact with two different materials (the surface treatment layer and the functional pad), Therefore, compared with the prior art, when the electronic package of the present disclosure undergoes thermal shock, the surface treatment layer having buffering capability can improve the reliability of the electronic package.

Furthermore, compared with the prior art that coated the strengthening layer on the entire top surface of the copper pad, the surface treatment layer in the manufacturing method of the present disclosure only forms on parts of the surface of the functional pad, thereby reducing the production cost.

### BRIEF DESCRIPTION OF THE DRAWINGS

FIG. 1A is a schematic cross-sectional view of a conventional semiconductor package.

FIG. 1B is a schematic cross-sectional view of another conventional semiconductor package.

FIG. 2A, FIG. 2B, FIG. 2C, FIG. 2D, FIG. 2E-1, FIG. 2F and FIG. 2G-1 are schematic cross-sectional views of an electronic package of the present disclosure.

FIG. 2E-2 is a schematic cross-sectional view showing another aspect of FIG. 2E-1.

FIG. 2G-2 is a schematic cross-sectional view showing another aspect of FIG. 2G-1.

FIG. 2H is a schematic cross-sectional view showing another embodiment of the electronic package of the present disclosure and its application.

FIG. 3A to FIG. 3C are schematic partial top views of FIG. 2B.

### DETAILED DESCRIPTION

Implementations of the present disclosure are described below by embodiments. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios or sizes are construed as falling within the scope covered by the technical contents disclosed herein. Meanwhile, terms such as “on,” “above,” “below,” “first,” “second,” “one,” “a,” “an,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

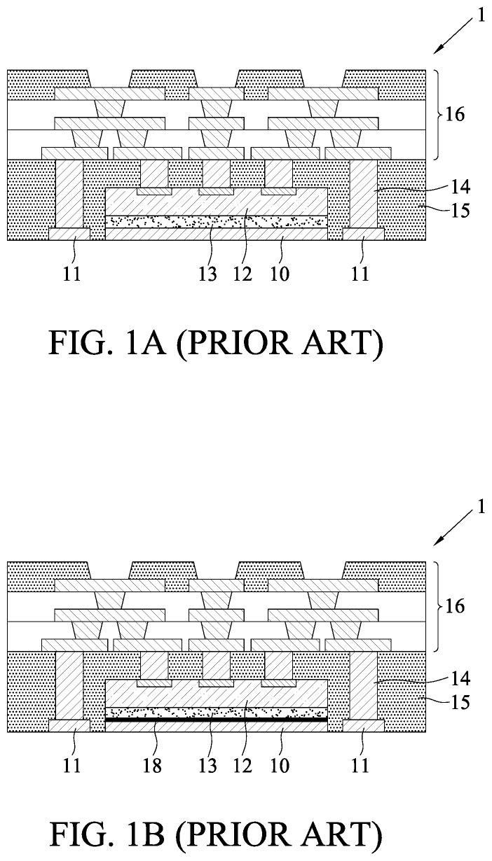

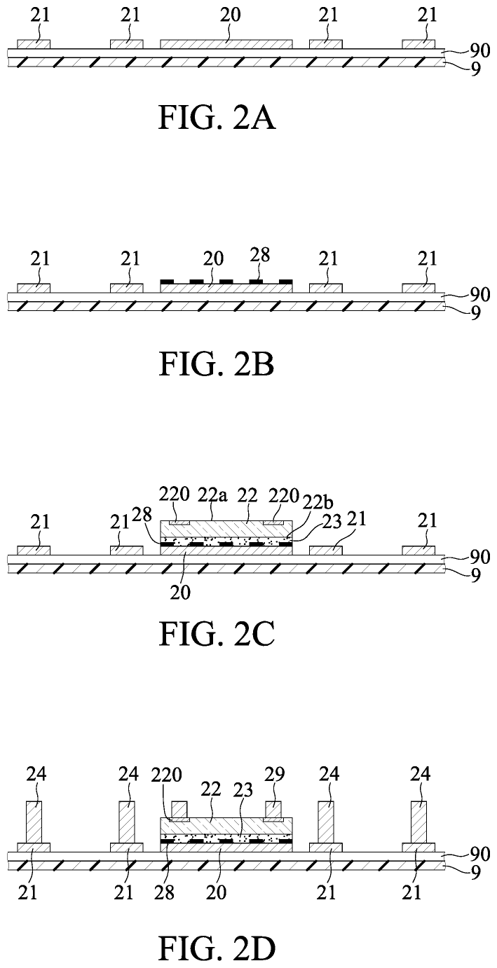

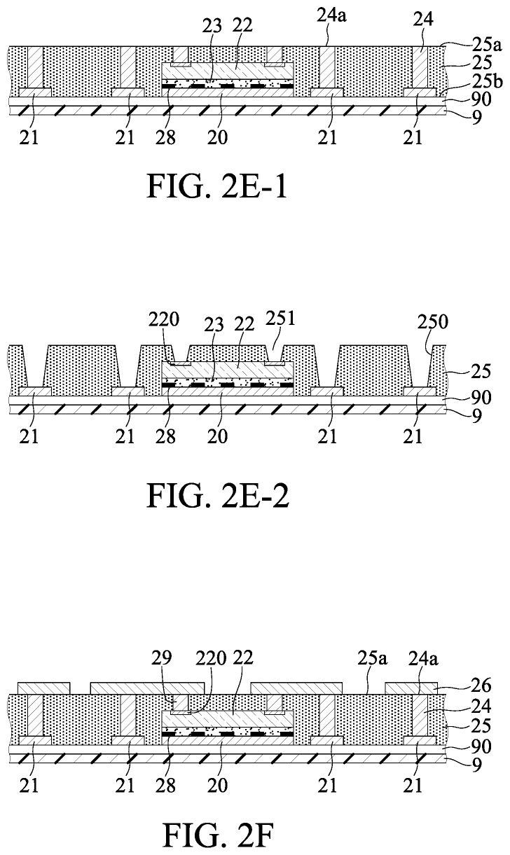

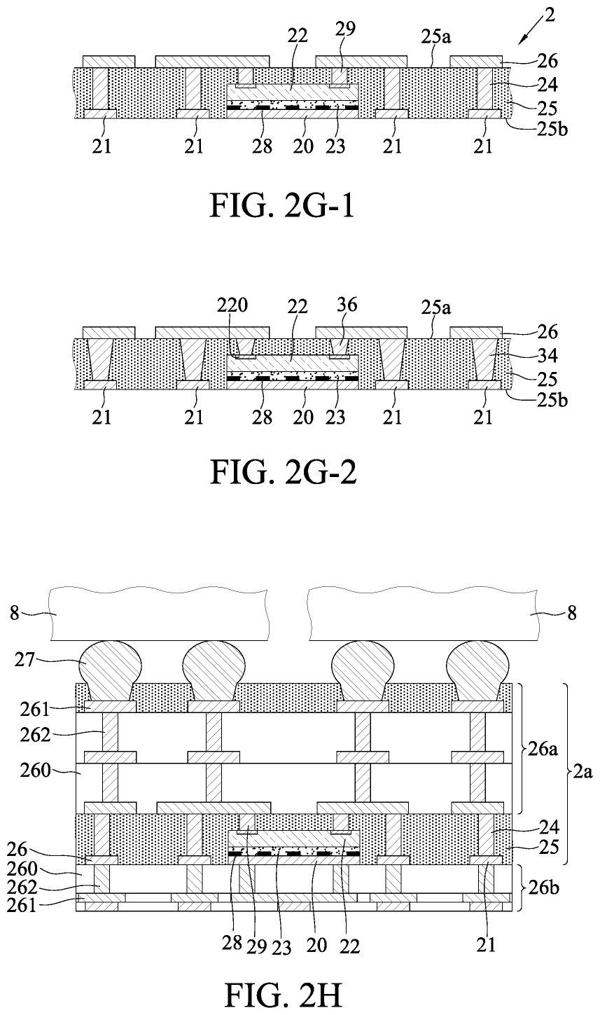

FIG. 2A, FIG. 2B, FIG. 2C, FIG. 2D, FIG. 2E-1, FIG. 2F and FIG. 2G-1 are schematic cross-sectional views illustrating a method of manufacturing an electronic package 2 of the present disclosure.

As shown in FIG. 2A, a carrier 9 having at least one metal surface is provided, and then a patterned metal layer including at least one functional pad 20 and a first circuit layer 21 is formed on the carrier 9.

In an embodiment, the carrier 9 is for example a copper foil substrate, so that the first circuit layer 21 and the functional pad 20 are disposed on the copper material of the copper foil substrate, and a release layer 90 can be formed on the carrier 9 according to requirements, so that the first circuit layer 21 and the functional pad 20 are disposed on the release layer 90.

Furthermore, the first circuit layer 21 and the functional pad 20 are simultaneously fabricated by patterned exposure and development. For example, a patterned copper layer is formed on the copper foil substrate (or the release layer 90) by electroplating or other methods, so that the patterned copper layer includes the first circuit layer 21 and the functional pad 20. For instance, the electroplating process uses a redistribution layer (RDL) process to fabricate the first circuit layer 21 and the functional pad 20.

As shown in FIG. 2B, a selective metallization process is performed on parts of the top surface of the functional pad 20 to form a surface treatment layer 28.

In an embodiment, a material of the functional pad 20 is different from a material of the surface treatment layer 28. For example, the functional pad 20 and the surface treatment layer 28 are made of different metal materials. For instance, the material for forming the surface treatment layer 28 is one of an alloy of the group consisting of silver, nickel, palladium and gold or a group consisting of multiple layers of metals, such as electroplating nickel/gold, electroless nickel plating/gold, electroless nickel immersion gold (ENIG), electroless nickel electroless palladium immersion gold (ENEPIG), electroless immersion tin, etc., but the present disclosure is not limited to the above.

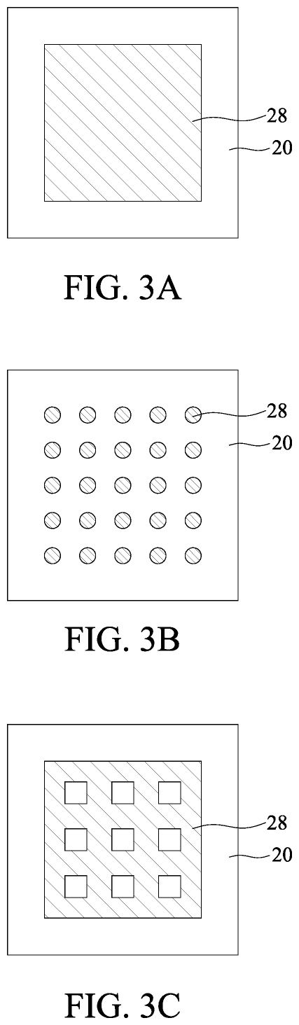

Furthermore, the surface treatment layer 28 is uniformly or non-uniformly distributed on parts of the surface of the functional pad 20. For example, the arrangement of the surface treatment layer 28 can be at least one piece (as shown in FIG. 3A), multi-dot (e.g., dotted shape as shown in FIG. 3B), or other patterns (e.g., grid shape as shown in FIG. 3C), as long as a part of the surface of the functional pad 20 is exposed (or the top surface of the functional pad 20 is not completely covered by the surface treatment layer 28).

As shown in FIG. 2C, a bonding layer 23 is formed on the functional pad 20 and the surface treatment layer 28, and then an electronic element 22 is disposed on the bonding layer 23, so that the electronic element 22 is disposed on the functional pad 20 and the surface treatment layer 28 via the bonding layer 23, and the surface treatment layer 28 is covered by the bonding layer 23, so that the bonding layer 23 is in contact with the functional pad 20 and the surface treatment layer 28 simultaneously.

In an embodiment, the electronic element 22 is an active element, a passive element, or a combination of the active element and the passive element, wherein the active element may be a semiconductor chip, and the passive element may be a resistor, a capacitor, or an inductor. For example, the electronic element 22 is a semiconductor chip and has an active surface 22a and an inactive surface 22b opposing the active surface 22a, wherein a plurality of electrical connection pads 220 are formed on the active surface 22a, and the electronic element 22 is fixed on the functional pad 20 and the surface treatment layer 28 via the bonding layer 23 with the inactive surface 22b of the electronic element 22.

Furthermore, the bonding layer 23 is an insulating adhesive or a conductive adhesive such as silver glue to adhere to two metal materials (i.e., the functional pad 20 and the surface treatment layer 28), so that the adhesive interface of the bonding layer 23 can have a buffering effect to ensure that the bonding layer 23 and the functional pad 20 can pass the reliability test. For example, the adhesive material of the bonding layer 23 can be hardened at high temperature, but the copper material of the functional pad 20 is easily oxidized in the high temperature, so that the functional pad 20 is deteriorated and the bonding property with the bonding layer 23 is affected. Since a metal material (i.e., the surface treatment layer 28) suitable for bonding the bonding layer 23 is formed on the functional pad 20, the surface treatment layer 28 having buffering capability/effect can avoid the problem of quality deterioration during the reliability test.

Also, the functional pad 20 is not only served as a die pad, but also served as a heat dissipation pad for the electronic element 22.

As shown in FIG. 2D, a plurality of conductive pillars 24 are formed on at least part of the first circuit layer 21 by patterned exposure and development.

In an embodiment, the material for forming the plurality of conductive pillars 24 is a metal material such as copper or a solder material.

Furthermore, columnar fan-out conductors 29 are formed by fan out on the electrical connection pads 220 of the electronic element 22 simultaneously when the plurality of conductive pillars 24 are formed. For example, the fan-out conductor 29 is a cylinder suitable for (e.g., conform to) the geometric shape of the electrical connection pad 220 of the electronic element 22, such as a square column, a circular column, or a short column with other cross-sectional shapes, and the present disclosure is not limited to the above.

As shown in FIG. 2E-1, a packaging layer 25 is formed on the carrier 9, so that the packaging layer 25 covers the first circuit layer 21, the functional pad 20, the electronic element 22 and the plurality of conductive pillars 24.

In an embodiment, the packaging layer 25 is defined with a first surface 25a and a second surface 25b opposing the first surface 25a, so that the second surface 25b of the packaging layer 25 is bonded onto the carrier 9 (or the release layer 90).

Furthermore, the material of the packaging layer 25 is an insulation material, which can be an organic dielectric material (e.g., solder mask material) or inorganic dielectric material (e.g., insulating oxides). For example, the types of the organic dielectric material may include Ajinomoto build-up film (ABF), pre-immersed material, molding compound, epoxy molding compound (EMC), or primer.

Also, a portion of the material of the packaging layer 25 is removed via the leveling process such as grinding method, so that the first surface 25a of the packaging layer 25 is flush with end surfaces 24a of the conductive pillars 24, such that the end surfaces 24a of the conductive pillars 24 are exposed from the first surface 25a of the packaging layer 25.

In addition, in other embodiments, as shown in FIG. 2E-2, the packaging layer 25 can also be formed first, and then the electrical connection pads 220 of the electronic element 22 can be exposed with openings 251 (where the openings 251 are formed by laser). Further, vias 250 are formed on the first surface 25a of the packaging layer 25, and then a conductive material is formed in the openings 251 and the vias 250, such that the conductive material becomes conductive blind vias 36 and conical conductive pillars 34, as shown in FIG. 2G-2.

As shown in FIG. 2F, following the process shown in FIG. 2E-1, a second circuit layer 26 is electroplated on the first surface 25a of the packaging layer 25 by patterned exposure and development, so that the second circuit layer 26 is electrically connected to the electronic element 22 and the plurality of conductive pillars 24.

In an embodiment, the second circuit layer 26 is a fan-out type redistribution layer (RDL). In another embodiment, following the process shown in FIG. 2E-2, when the second circuit layer 26 is formed, as shown in FIG. 2G-2, the plurality of conductive blind vias 36 and the conductive pillars 34 are simultaneously formed, so that the plurality of conductive blind vias 36 are electrically connected to the second circuit layer 26 and the electrical connection pads 220 of the electronic element 22.

Furthermore, the second circuit layer 26 is in contact with the end surfaces 24a of the conductive pillars 24 and electrically connected with the conductive pillars 24. It should be understood that if the end surfaces 24a of the conductive pillars 24 are not exposed from the first surface 25a of the packaging layer 25, the second circuit layer 26 can be electrically connected to the conductive pillars 24 by the conductive blind vias 36.

As shown in FIG. 2G-1, the carrier 9 and the release layer 90 thereon are removed to expose the second surface 25b of the packaging layer 25, the functional pad 20 and the bottom surface of the first circuit layer 21, so that the bottom surface of the first circuit layer 21 is served as an external pad.

Furthermore, in other embodiments, at least one build-up circuit structure 26a may also be formed on the second circuit layer 26 (or the first surface 25a of the packaging layer 25) in a manner of build-up method, as an electronic package 2a shown in FIG. 2H, the build-up circuit structure 26a is electrically connected with the electronic element 22 and the conductive pillars 24, and the build-up circuit structure 26a has a plurality of dielectric layers 260, a plurality of second circuit layers 261 disposed on the dielectric layer 260 and a plurality of conductive blind vias 262 disposed in the dielectric layer 260 and electrically connected to the second circuit layers 261, wherein the dielectric material of the dielectric layer 260 is, for example, polybenzoxazole (PBO), polyimide (PI), prepreg (PP), or the like.

In the subsequent process, the electronic package 2, 2a can be formed with a plurality of conductive elements 27 such as solder balls on the second circuit layer 26, 261 (as shown in FIG. 2H) for external connecting such as at least one semiconductor chip, passive elements (e.g., multi-layer ceramic capacitors or low inductance ceramic capacitors), a circuit board, or an electronic device 8 of another package (as shown in FIG. 2H). It should be understood that another build-up circuit structure 26b (as shown in FIG. 2H) can also be formed on the second surface 25b of the packaging layer 25 and the first circuit layer 21 for external connecting such as semiconductor chips, passive elements, a circuit board, or an electronic device of another package (not shown).

In the manufacturing method of the present disclosure, the surface treatment layer 28 is formed on parts of (partial) the top surface of the functional pad 20, so that the bonding layer 23 is in contact with two different metal materials (the surface treatment layer 28 and the functional pad 20) at the same time, such that the surface treatment layer 28 has buffering capability/effect when the electronic package 2, 2a undergoes thermal shock, thereby improving the reliability of the electronic package 2, 2a. For example, if the chemical bonding force between the functional pad 20 and the bonding layer 23 is not as expected, the surface treatment layer 28 can be used as a buffer layer between the functional pad 20 and the bonding layer 23 to improve the reliability of the electronic package 2, 2a under thermal shock.

Furthermore, compared with the strengthening layer that is coated on the entire top surface of the conventional copper pad, the surface treatment layer 28 in the manufacturing method of the present disclosure only forms on parts of (partial) the top surface of the functional pad 20, thereby reducing the production cost.

The present disclosure further provides an electronic package 2a, which comprises: a patterned metal layer comprising at least one functional pad 20 and a first circuit layer 21, a surface treatment layer 28 disposed on parts of a surface of the functional pad 20, a bonding layer 23, an electronic element 22 disposed on the bonding layer 23, a packaging layer 25 and a build-up circuit structure 26a.

The electronic element 22 and the patterned metal layer are covered by the packaging layer 25 having a first surface 25a and a second surface 25b opposing the first surface 25a, and a part of a bottom surface of the first circuit layer 21 is exposed from the packaging layer 25 to be served as an external pad.

The functional pad 20 is embedded in the packaging layer 25 from the second surface 25b.

The surface treatment layer 28 is disposed on parts of the surface of the functional pad 20.

The bonding layer 23 is disposed on the functional pad 20 and the surface treatment layer 28.

The electronic element 22 is disposed on the functional pad 20 and the surface treatment layer 28 via the bonding layer 23 and is provided with a plurality of electrical connection pads 220.

The build-up circuit structure 26a is bonded with the packaging layer 25 and electrically connected to the electrical connection pads 220 of the electronic element 22 and the first circuit layer 21.

In one embodiment, the surface treatment layer 28 is uniformly or non-uniformly distributed on parts of the surface of the functional pad 20.

In one embodiment, a material of the functional pad 20 is different from a material of the surface treatment layer 28. For example, the functional pad 20 and the surface treatment layer 28 are made of different metal materials.

In one embodiment, the bonding layer 23 is a conductive adhesive or an insulating adhesive.

In one embodiment, the build-up circuit structure 26a is electrically connected to the electrical connection pads 220 of the electronic element 22 via a plurality of fan-out conductors 29, and the fan-out conductors 29 are formed as cylinders conformed to a geometry of the electrical connection pads 220 of the electronic element 22.

In view of the above, in the electronic package of the present disclosure and a manufacturing method thereof, the surface treatment layer 28 is formed on parts of the top surface of the functional pad 20, so that the bonding layer 23 is in contact with two different metal materials at the same time, and the surface treatment layer 28 is used as a buffer layer, such that the reliability of the electronic package of the present disclosure can meet the requirements.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a patterned metal layer comprising at least one functional pad and a first circuit layer;
a surface treatment layer disposed on parts of a surface of the functional pad;
a bonding layer disposed on the functional pad and the surface treatment layer;
an electronic element disposed on the bonding layer and being bonded onto the functional pad and the surface treatment layer via the bonding layer, wherein the electronic element is provided with a plurality of electrical connection pads;
a packaging layer covering the electronic element and the patterned metal layer, wherein a part of a bottom surface of the first circuit layer is exposed from the packaging layer to serve as an external pad; and
a build-up circuit structure bonded with the packaging layer and electrically connected to the electrical connection pads of the electronic element and the first circuit layer.

2. The electronic package of claim 1, wherein the surface treatment layer is uniformly or non-uniformly distributed on the parts of the surface of the functional pad.

3. The electronic package of claim 1, wherein the functional pad and the surface treatment layer are made of different metal materials.

4. The electronic package of claim 1, wherein the bonding layer is a conductive adhesive or an insulating adhesive.

5. The electronic package of claim 1, wherein the build-up circuit structure is electrically connected to the electrical connection pads of the electronic element via fan-out conductors.

6. The electronic package of claim 5, wherein the fan-out conductors are formed as cylinders conformed to a geometry of the electrical connection pads of the electronic element.

7. A method of manufacturing an electronic package, comprising:
providing a carrier having at least one metal surface;
electroplating a patterned metal layer on the carrier by patterned exposure and development, wherein the patterned metal layer comprises at least one functional pad and a first circuit layer;
forming a surface treatment layer on parts of a surface of the functional pad;
forming a bonding layer on the functional pad and the surface treatment layer;
disposing an electronic element on the bonding layer, wherein the electronic element has a plurality of electrical connection pads;
forming a plurality of conductive pillars on a part of the first circuit layer by patterned exposure and development;
covering the electronic element and the plurality of conductive pillars by a packaging layer;
electroplating a second circuit layer on the packaging layer by patterned exposure and development, wherein the second circuit layer is electrically connected to the electronic element and the plurality of conductive pillars; and
removing the carrier to expose a part of a bottom surface of the first circuit layer for serving as an external pad.

8. The method of claim 7, wherein the surface treatment layer is uniformly or non-uniformly distributed on the parts of the surface of the functional pad.

9. The method of claim 7, wherein the functional pad and the surface treatment layer are made of different metal materials.

10. The method of claim 7, further comprising forming column-shaped fan-out conductors simultaneously on the electrical connection pads of the electronic element when forming the plurality of conductive pillars.

11. The method of claim 10, wherein the fan-out conductors are cylinders conformed to a geometry of the electrical connection pads of the electronic element.

12. The method of claim 7, further comprising exposing the electrical connection pads of the electronic element with openings formed by a laser after forming the packaging layer, and forming conductive blind vias simultaneously when forming the second circuit layer subsequently, wherein the conductive blind vias are electrically connected to the second circuit layer and the electrical connection pads of the electronic element.
